(19) United States
(12) Patent Application Publication
(10) Pub. No.: US 2005/0242367 A1
(43) Pub. Date: Nov. 3, 2005

(54) Thin-film electronic device, in particular power device, and method for making same

(76) Inventors: Laurent Clavelier, ST. MARTIN D'HERES (FR); Eric Jalaguier, Saint Martin D'Uriage (FR)

Correspondence Address: Thelen Reid & Priest, P O Box 640640, San Jose, CA, 95164-0640, US

(21) Appl. No.: 10/520,646

(22) PCT Filed: Jul. 2, 2003
(86) PCT No.: PCT/FR03/02057

§ 371 Date: Jan. 5, 2005

(30) Foreign Application Priority Data
Jul. 5, 2002 (FR) 02/08453

(51) Int. Cl. H01L 29/74

(52) U.S. Cl. 257/107; 438/133

(57) ABSTRACT

Thin-layer electronic device, in particular a thin-layer power device, and process for fabricating this device.

According to the invention, an electronic device is formed comprising an active part (38,40,42), a first thin layer (36) which is made of a semiconductor material and in which this active part is formed, and a substrate (44) which is made of a conductive material. This device also comprises a carrier recombination zone (46) which is located between the substrate and the first thin layer and which also ensures a resistive electric contact between this substrate and this first thin layer.

### TECHNICAL FIELD

The present invention concerns a thin-layer electronic device, in particular a microelectronic thin-layer power device, and a process for fabricating this device.

It applies in particular to control devices for electric motors and to voltage converters.

Microelectronic power devices, or microelectronic power components, are structures formed on semiconductor substrates. They are generally used as switches to obtain energy conversion members.

Most of these components are of vertical structure: in a component of this type, the current circulates between the front side and the rear side of the substrate on which it is formed.

A power component is characterized by two main parameters:
its voltage resistance, which is dependent upon the thickness and resistivity of the substrate on which it is formed, and
its current rating which is dependent upon the active surface of the component, this surface being the smallest possible for cost-related reasons.

Power components are classified in two categories, as per their conduction type:
the category of unipolar conduction components, in which a single carrier type participates in current circulation, this category including MOS transistors for example, and
the category of bipolar conduction components, in which both types of carrier participate in conduction, this category including IGBTs for example (Insulated Gate Bipolar Transistors).

One aspect of optimising a power component consists of reducing its losses, at given voltage rating and current density. There are four types of losses:
losses due to changeover from a non-conductor state to a conductor state, called OFF=>ON losses, which for the most part are imposed by elements outside the component under consideration (circuit),
losses due to the conductor state, called ON-state losses or ON-static losses, whose reduction (at a fixed current rating) requires a reduction in voltage drop at the terminals of the component under consideration when the latter is conducting current, which entails reducing its ON resistance denoted Ron (conductor state resistance),
losses due to the changeover from the conductor state to a non-conductor state, called ON=>OFF losses, and
losses due to the non-conductor state, called OFF-state losses or OFF-static losses, which are negligible compared with the other losses.

In the present invention, attention is given to reducing ON-static losses and ON=>OFF switching losses, in particular in bipolar components (IGBTs for example).

As has been seen, to reduce losses in the ON-state of a power component (at a fixed current rating), the voltage drop at the terminals of this component must be reduced when the component is conducting current. This entails reducing the ON resistance (Ron) of this component.

To reduce this Ron resistance, there are four possibilities:
it is possible to reduce the thickness of the component's substrate; the most that is needed is 0.1 μm thickness per volt of voltage tolerance, i.e. a thickness of 60 μm for a component having a voltage tolerance of 600V.

At the present time, limitation of thickness encounters a problem of mechanical performance: the thinner the substrate wafer, the more it is fragile.
it is possible to increase the active surface for current passing. This is achieved to the detriment of cost; it is rather more sought to achieve maximum reduction of the active zone surface area.
it is possible to reduce the resistivity of the substrate; at a given voltage tolerance an optimum exists for substrate resistivity.
it is possible to increase the injection of minority carriers in the low-doped zone of the component. With IGBT components, all that is needed in this respect is to form a highly doped P+ layer on the rear side of this component. But this is done to the detriment of ON=>OFF switching losses. A compromise must therefore be found between ON-state characteristics and ON=>OFF switching characteristics.

To simultaneously reduce ON-state losses and ON=>OFF switching losses, one solution which may be considered is:
reducing the thickness of the substrate to the minimum required by voltage tolerance, and
optimising injection via the rear side by choosing the best compromise between ON=>OFF losses and ON voltage drop.

This compromise is dictated by the type of application in which it is desired to use the power component. The lower limit is chosen for injection via the rear side, which does not lead to degradation of the conductor state characteristics, or ON characteristics, of the component. Simply, a less efficient emitter is made.

It is to be noted that the present invention also applies to the fabrication of unipolar components and bipolar components on ultra-thin wafers, whose fabrication requires treatment steps (for example lithography, etching, implanting) on the rear side of these wafers.

### STATE OF THE PRIOR ART

It is known to form a power component on a “standard” bulk substrate. The latter is initially homogenous: doping is identical at every point of this substrate.

The thickness of the substrate is not optimised for the intended voltage tolerance. For example, for a component of 600V type, from an electric viewpoint, a substrate would suffice having a thickness of 60 μm instead of thicknesses of more than 200 μm usually used.

ON-state losses may be reduced by forming a highly efficient emitter to the detriment of ON=>OFF losses, or vice versa.

When using “standard” bulk substrates a compromise must be found between the reduction of ON-losses and the reduction of ON=>OFF losses.

It is also known to thin a substrate at the end of the fabrication process of a power component on this substrate. In this way a component is obtained on an ultra-thin wafer.

The initial steps of the process are performed on a standard wafer the thickness of which is more than 300 μm, then this wafer is thinned via the rear side until the desired thickness is obtained, for example down to 70 μm for substrates 150 mm in diameter. Subsequently, the rear side steps are performed, taking care to reduce the number thereof to a minimum.

By optimising rear side doping and annealing operations, it is possible to obtain an emitter whose efficiency is sufficiently high so as not to deteriorate Ron and sufficiently low to reduce ON=>OFF switching losses.

On this point, the following documents may be consulted:

T. LASKA, M. MATSCHITSCH & W. SCHOLZ, “Ultra-thin wafers technology for a new 600V-NPT-IGBT”, ISPSD′1997, 1997, pages 361 to 364.

T. LASKA, M. MUNZER, F. PFIRSCH, C. SCHAEFFER & T. SCHMIDT, “The Field Stop IGBT (FS IGBT), a new power device concept with a great improvement potential”, ISPSD′2000, May 2000, pages 355 to 358.

This technique of thinned wafers at the end of the process makes it possible to obtain thin wafers with an emitter of low efficiency, whose P+ layer is obtained with a low implanted dose and low diffusion, which simultaneously reduces ON-static losses and ON=>OFF dynamic losses.

However, the use of this technique is limited by the robustness of the wafers: the thinner the wafers, the more mechanical performance is reduced.

Therefore the users of this technique are currently limited to a thickness of 70 μm for wafers of 6-inch diameter (approximately 15 cm). They cannot move up to 8-inch wafers (approximately 20 cm) while maintaining this thickness of 70 μm.

In addition, to reduce the “electric thickness” (i.e. the electrically active thickness) of a power component, it is known to form this component on an epitaxied substrate.

This a highly resistive layer of narrow thickness, deposited on a highly doped semiconductor substrate, the power component being formed on the side of the substrate with high resistivity.

With this technique it is possible to reduce voltage drop when the current is passing, and hence ON-state losses, since the resistive layer is of narrow thickness (being optimised for the required voltage tolerance).

But this technique does not make it possible to reduce ON=>OFF switching losses since the rear side emitter consists of a P+ “sole” that is very thick and highly doped. This leads to a high injection of minority carriers in the scarcely doped zone and leads to long ON=>OFF switching times and hence to high losses.

To reduce this rear side injection, an N zone may be inserted just above the P+ zone during the fabrication of the substrate. A P+/N junction is then obtained which injects fewer minority carriers into the N− zone than a P+/N− junction.

It is to be noted that this technique is sometimes used during the fabrication of components on standard wafers or on thin wafers.

The technique using epi substrates therefore allows a reduction in ON-losses but leads to relatively high ON=>OFF losses.

The prior art set forth above is very schematically illustrated in FIGS. 1 to 3.

The technique using a “standard” bulk semiconductor substrate is very schematically illustrated in FIG. 1 in which this substrate 2 can be seen in which a power component 4 is formed having a vertical structure. This component comprises zones which are implanted in the substrate.

For example, assuming that substrate 2 is of N type, a zone 6 of P type is implanted on the front side of this substrate, several zones 8 of N+ type are implanted in this zone 6, and another zone 10 of P type, of narrow thickness, is implanted on the rear side of the substrate.

In FIG. 1, reference 12 symbolizes electric contacts associated with zones 6 and 8, and reference 14 symbolizes an electric contact associated with zone 10.

The technique using a semiconductor substrate that is thinned at the end of the fabrication process of the power component is very schematically illustrated in FIG. 2, in which one can see this substrate 16 and this component 4 whose structure is identical to the one described above, with reference to FIG. 1, but which is formed in this substrate 16.

The technique using an epitaxied semiconductor substrate is very schematically illustrated in FIG. 3 in which a semiconductor substrate 18 can be seen, for example of P+ type, having very low resistivity and comprising a zone 20 of N type on its front side.

On this zone 20, a semiconductor zone 22 of narrow thickness and of N− type is epitaxied. The power component 24 which is formed on the epi substrate, in this zone 22 and on its front side, comprises an implanted zone 26 of P type and several zones 28 of N+ type which are implanted in this zone 26.

In FIG. 3, reference 30 symbolizes electric contacts associated with zones 26 and 28, and reference 32 symbolizes an electric contact which is formed on the rear side of substrate 18.

### DESCRIPTION OF THE INVENTION

The purpose of the present invention is to overcome the above-mentioned disadvantages in respect of these three known techniques.

Its subject is firstly an electronic device comprising an active part, a first thin layer made of a semiconductor material and in which this active part is formed, and a substrate made of an electrically conductive material, this device being characterized in that it also comprises a carrier recombination zone, which is located between the substrate and the first thin layer and which also ensures a resistive electric contact between this substrate and this first thin layer.

According to one preferred embodiment of the device of the invention, the carrier recombination zone is a second thin layer made of an electrically conductive material and which ensures electrically conductive bonding between the substrate and the first thin layer.

According to one particular embodiment of the device of the invention, the two sides of the first thin layer are treated to form active zones of the device.

The material in which the carrier recombination zone is made may be a metal.

As a variant, the material in which the carrier recombination zone is made is a semiconductor/metal alloy.

This alloy in which the carrier recombination zone is made is preferably chosen so that it is stable with respect to the materials in which the substrate and the first thin layer are respectively made.

The material in which the substrate is made may be a highly doped semiconductor, in particular highly doped silicon.

In this case, the material in which the carrier recombination zone is made may be a metal, this metal being chosen so that, when fabricating the resistive electric contact, it forms a stable alloy with the highly doped semiconductor in which the substrate is made and with the semiconductor material in which the first thin layer is made.

As a variant, the material in which the substrate is made is a metal.

In this case, the carrier recombination zone may be made in the metal in which the substrate is made and is formed by part of this substrate.

The present invention also concerns a process for fabricating an electronic device, this process being characterized in that it comprises the following steps:
part of the device is formed in a standard semiconductor substrate, on the front side of this standard semiconductor substrate,
a treatment support is fixed to the front side of the substrate,
the standard semiconductor substrate is thinned via its rear side to transform it into a thin layer,
another part of the device is formed in the standard semiconductor substrate so transformed, on the rear side of this standard semiconductor substrate,
on the rear side of this standard semiconductor substrate and/or on a side of an electrically conductive substrate, a thin layer is deposited formed of a metal or of a metal/semiconductor alloy,
via the thin layer, formed of the metal or metal/semiconductor alloy, electrically conductive bonding is carried out between the electrically conductive substrate and the thin layer into which the standard semiconductor substrate was transformed, and
the treatment support is removed.

In addition, the present invention concerns a process for fabricating an electronic device, this process being characterized in that it comprises the following steps:
part of the device is formed in a standard semiconductor substrate, on the rear side of this standard semiconductor substrate,
on the rear side of this standard semiconductor substrate and/or on a side of an electrically conductive substrate, a thin layer is deposited formed of a metal or of a metal/semiconductor alloy,
electrically conductive bonding is carried out between the electrically conductive substrate and the standard semiconductor substrate, via the thin layer,
the standard semiconductor substrate is thinned via its front side to transform it into a thin layer, and
another part of the device is formed in the standard semiconductor substrate so transformed, on the front side of this standard semiconductor substrate.

It is also possible to form electric contacts of the device on the thin layer, in which the standard semiconductor substrate was transformed, and on the electrically conductive substrate.

The electrically conductive substrate may be made of a material chosen from among highly doped semiconductors in particular highly doped silicon, and conductors in particular metals.

In particular, the electrically conductive substrate may be made of a material chosen from among highly doped semiconductors, in particular highly doped silicon, the metal or the metal/semiconductor alloy being chosen so that, after annealing subsequent to electrically conductive bonding, it forms a stable alloy with the material in which the electrically conductive substrate is made and with the material in which the standard semiconductor substrate is made.

Preferably, the electrically conductive bonding step is preceded by a preparative step to prepare at least one of the two sides to be assembled by electrically conductive bonding to promote such bonding.

Preferably also, the electrically conductive bonding is chosen from among bonding by soldering, bonding by thermal compression and bonding by molecular adhesion.

### BRIEF DESCRIPTION OF THE DRAWINGS

The present invention will be more readily understood on reading the following description of examples of embodiments, which are given solely for guidance and are in no way restrictive, with reference to the appended drawings in which:

FIGS. 1 to 3 very schematically illustrate known techniques for fabricating power devices on a standard bulk substrate (FIG. 1), on a substrate thinned at the end of the process (FIG. 2) and on an epitaxied substrate (FIG. 3) respectively, and have already been described,

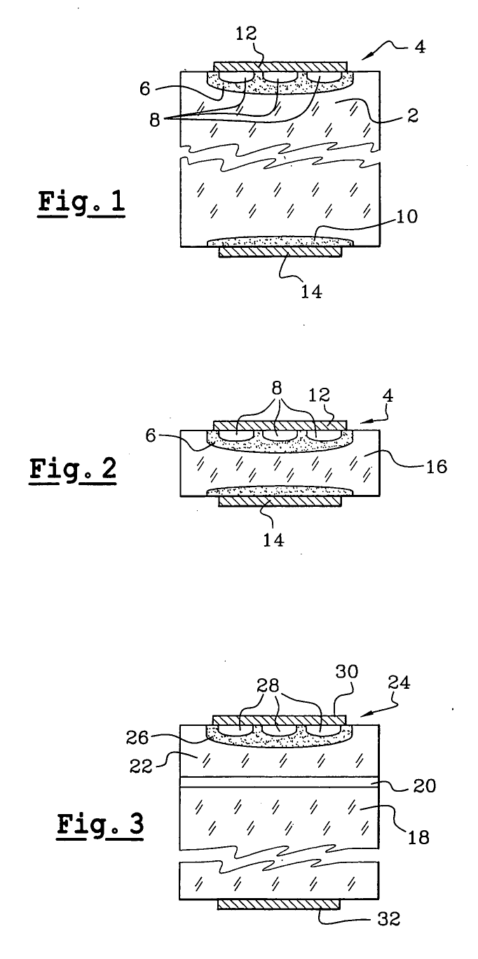

FIG. 4 is a schematic section view of a particular embodiment of the device that is the subject of the invention, and

FIGS. 5A to 5D schematically illustrate various steps of a particular embodiment of the process that is the subject of the invention.

### DETAILED DESCRIPTION OF PARTICULAR EMBODIMENTS

According to a process of the invention, an electronic component, more particularly a power component, is formed in a thin layer of a semiconductor material. The thickness of the component is therefore limited to the thickness of a thin layer (200 μm or less, typically of the order of 50 μm or less).

This layer, via electrically conductive bonding, is then mounted on a substrate whose function is twofold: this substrate ensures the mechanical resistance of the assembly and current contacting at the rear side of the component, without acting upon the functioning of the component.

A process is therefore proposed for fabricating power components whose electric thickness is narrow, typically 50 μm with double-side treatment, and whose mechanical thickness is standard, typically of the order of 500 μm for a processed substrate 100 mm in diameter.

With this process it is possible to reduce ON-state losses and ON=>OFF switching losses simultaneously (the same ON and ON=>OFF losses are obtained as with a component formed on an ultra-thin wafer, in accordance with a known technique mentioned above) while having a substrate whose mechanical resistance is that of a “standard” substrate (the same mechanical rigidity is obtained as with standard or epitaxied wafers mentioned above).

The proposed process does not lead to limitation of dimensions, both regarding the respective thicknesses of the thin wafer, or thin layer, and of the support wafer, or support substrate, and regarding the respective diameters of these wafers (which generally have the same diameter).

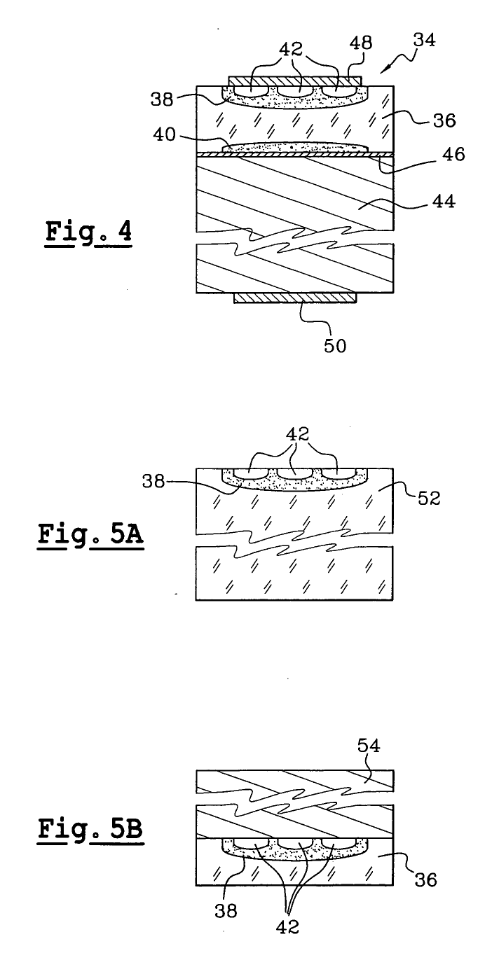

FIG. 4 is a schematic section view of a particular embodiment of the device that is the subject of the invention. It is for example a surge arrester 34 which is formed on a thin semiconductor wafer 36.

Zones 38 and 40 are respectively implanted on the front side and rear side of this wafer 36. Zones 42 can also be seen which are implanted in zone 38. This zone 38 and zone 40 are active zones of the device.

The surge arrester 34 also comprises a support wafer 44 which is scarcely resistive and whose front side is in electric contact, or resistive contact, with the rear side of the thin wafer 36 via metal bonding 46.

In addition, electric contacts 48 and 50 are formed on the front side of the thin wafer 36 and on the rear side of the support wafer 44.

The thin wafer 36 is therefore the electrically active wafer on which a power component 34 is formed (surge arrester) whose electric thickness (typically 50 μm or less) corresponding to the thickness of the thin wafer 36, is very narrow.

Unlike components made on epitaxied wafers, this wafer comprises treated zones (for example by lithography or etching) on its two sides (whereas an epitaxied wafer only comprises a single treated side, namely the front side).

The emitter (zone 40, for example of P+ type) contained in the component has low efficiency resulting from a low implanted dose and low diffusion (but it is also possible to insert an N zone before fabricating the P+ zone to reduce the efficiency of the emitter).

This emitter may be formed on the rear side of the wafer 36 at the end of the treatment of this wafer, before it is bonded to the support wafer 44.

This support wafer (which is for example a Si wafer that is scarcely resistive) does not play any active part in the functioning of the component. It simply ensures bringing current from contact 50, or rear side contact, to the rear side of the thin wafer 36 and must be as conductive as possible to reduce ON-state losses to a maximum.

This wafer 44 is not necessarily in silicon. It may be made of another semiconductor, metal or any conductor material (a conductive polymer for example).

This support wafer 44, as has been seen, ensures the mechanical rigidity of the assembly.

Metal bonding 46 ensures resistive electric contact between the two wafers 36 and 44. The resistance value of this contact must be as low as possible to reduce ON-state losses.

To achieve resistive bonding which meets these requirements, the surface concentrations of the dopants must be sufficiently high (on the rear side of the active wafer (wafer 36) and on the front side of the support wafer 44 if it is made of a semiconductor material).

The minimum concentration depends upon the type of metal chosen for metal bonding. If surface doping is insufficient, a Schottky diode may be obtained in series with the fabricated component, which is not the targeted objective.

This metal bonding is a recombination zone for all carriers. For example, if the support wafer 44 is a highly doped P+ wafer and the emitter is a P+ layer, the metal layer makes it possible to avoid the situation encountered with epitaxied wafers by forming a carrier recombination zone which acts as a rupture zone for semiconductor physical phenomena between the two wafers 36 and 44.

A power component is therefore obtained which is formed on a thin wafer and comprises a low-efficiency emitter (and/or is formed using a process comprising technological steps on the rear side, such as, for example, lithography operations on this rear side and alignment using the front side).

In addition, the mechanical rigidity of this power component is the same as with a component made on a thick wafer.

In this way, low ON-losses and low ON=>OFF switching losses are obtained with mechanical performance comparable to those obtained when fabricating components on “standard” wafers.

An example of fabrication of a vertical power component is described below, fabricated on an electrically ultra-thin and mechanically thick wafer according to the invention.

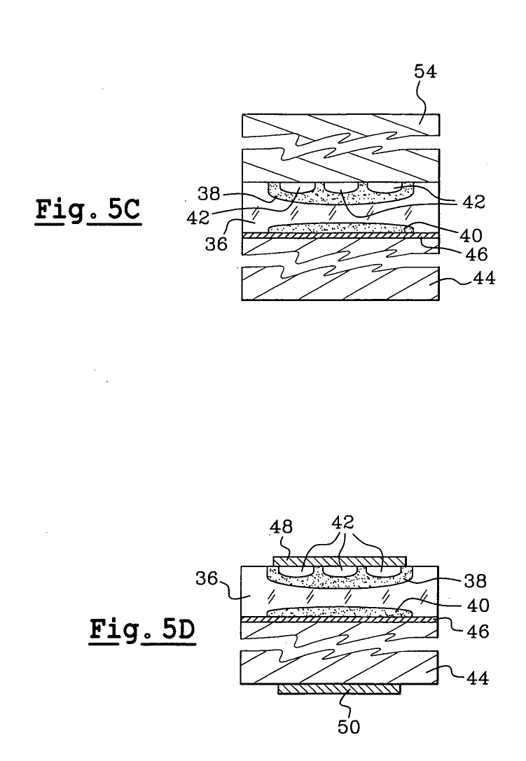

Throughout this technological process, it will be noted that no thin wafer is handled directly and that handles are used at all times (front side support 54 in FIG. 5B) to maintain a “standard” thickness, which guarantees good rigidity and enables the use of “standard” microelectronic equipment and processes.

1. The starting material is an active wafer 52 (FIG. 5A) of standard thickness (large thickness) on which front side technological steps are performed: implanted zones 38 and 42, already mentioned in the description of FIG. 4, are formed.

2. After optionally transferring alignment markings onto the rear side of the active wafer 52, a support wafer 54 which acts as handle, is bonded to the front side of the active wafer 52 (FIG. 5B).

The alignment markings may for example be specific alignment patterns (crosses or register marks) or diffraction gratings enabling the alignment of mask levels in relation to one another.

The alignment markings are optionally added to the front side of the support wafer 54.

The rear side of the active wafer 52 is then thinned down to the desired thickness (for example 60 μm for a voltage tolerance of 600V). In this manner, the thin active wafer 36 in FIG. 4 is obtained from the thick wafer 52.

It is to be noted that the total thickness of wafer 36 and support 54 is high.

3. The treatment steps of the rear side of the active thin wafer 36 are conducted (formation of zone 40).

If alignments are necessary, they can be made since alignment markings exist on the front side of support 54.

The conductor support 44 (scarcely resistive support wafer) is bonded to the rear side of the thin wafer 36 via the metal interface 46 (FIG. 5C).

4. The support wafer 54 is then removed (by detaching, elimination or another method), the treatment of the rear side of active plate 36 is completed and the front side and rear side contacts 48 and 50 are formed.

In a variant of the process just described, it is possible to treat firstly the rear side of the thick wafer 52, to bond this rear side to the conductive support 44 via metal bonding 46, to thin the thick wafer 52 via its front side and to treat the front side of the thin wafer obtained 36 to form zones 38 and 42 therein. In this case, there is no need for a support handle.

However, in this case, the treatment of the rear side of the thick wafer 52 requires heating using a higher heat schedule than for the front side, which limits possibilities for the rear side (in particular concerning dopant profiles and conductive bonding).

Components were formed on thin substrates, 100 μm thick, using the preceding process. For example, a surge voltage arrester was formed:

1. P and N+ zones were formed on the front side of a silicon wafer 4 inches(approximately 10 cm) in diameter and 550 μm thick, forming an active wafer.

2. After depositing a thick layer of silicon oxide on the front side of this wafer and planarizing this layer, a support handle was bonded to the front side, this handle being 550 μm thick.

The active wafer was thinned via its rear side down to a thickness of 100 μm. At this point, the assembly formed by the handle and the active wafer was 650 μm thick.

3. The rear side of the active wafer was treated (photo-lithography, etchings, P+ implanting, annealings at temperatures of over 1000° C.).

A deposit of palladium a few dozen nanometres thick was formed on the rear side of the active wafer, and another deposit of the same thickness was formed on a support wafer in N+ doped silicon, having a resistivity of a few mohms.cm and a thickness of 550 μm.

After cleaning the surfaces and contacting the surfaces to be bonded, appropriate annealing was performed. At this stage, the treated wafer was 1200 μm thick.

4. The upper wafer forming the handle was removed, the openings for the electric contacts were formed then metallisations of the front side and rear side were formed (deposit, photolithography, etching and annealing of the metal).

At the end of this process, the thickness of the wafer was 650 μm.

Measurements of dynamic characteristics were taken on the components so fabricated and showed the advantage resulting from the formation of said components on ultra-thin wafers treated on both their sides:

Voltage arrest is much more marked and switching edges are greater than with components formed in conventional manner, while reducing static losses, as compared with components formed on standard wafers.

Different metallic sealing techniques are known for bonding two wafers in semiconductor materials.

Soldering may be used, a welding method which consists of assembling two materials by re-melting a non-ferrous metal.

Sealing by soldering uses relatively thick layers called “preforms” around 50 μm thick. In this case the fusible alloys used are of SnPb type (whose melting point Mp is 180° C.), AuSn (Mp=280° C.) or AuSi (Mp=460° C.).

Sealing by soldering can also use thin layers having a thickness of a few micrometers. The fusible metals used may be of AuSn(80/20), SnPb or Ni type.

Sealing by thermal compression is another possibility using metal layers, for example layers of Ti or Ta.

These techniques are rather more used for the hybridization of small-sized components. Their application to the bonding of larger-sized surfaces (the case for wafers in semiconductor materials) is nonetheless a delicate operation:

For these sealing techniques, relatively thick metal layers are used, several micrometers, even several dozen micrometers thick.

The mechanical resistance of these metal layers is therefore uncertain, as is the mechanical resistance of the semiconductor wafer/metal alloy/semiconductor wafer bonded assembly during heat treatment, in particular on cooling, on account of the strong difference between the thermal expansion coefficients of the metals and semiconductors.

This is why bonding techniques by molecular adhesion are preferred.

Bonding by molecular adhesion, or “direct wafer bonding” is a process in which two surfaces adhere to one another at room temperature without the need for adhesive or external forces.

Such bonding takes place when the two surfaces to be sealed are sufficiently smooth and clean and are separated from one another by a very short distance, of the order of 10 to 100 nanometres. The attractive forces between the two surfaces then become sufficiently great for them to be drawn towards one another. After initiation at a contact point, spontaneous propagation of adhesion occurs.

This technique differs from the other sealing methods through the fact that it enables the bonding of large surfaces of semiconductor wafers at room temperature. The success of this type of bonding, in terms of bonding defects and adhesion forces, is essentially based on know-how and skill in cleaning the surfaces to be contacted.

Molecular adhesion bonding may be used to electrically connect two semiconductor wafers. In this case, typically, a thin layer of an appropriate metal, whose thickness is less than 1 μm, is coated onto one of the two surfaces to be bonded or on both these surfaces.

Metal bonding, by molecular adhesion, is being studied by numerous research teams whose work has enabled testing the capacity to bond various metal layers, essentially deposited on silicon.

According to a process of the invention, a thin layer of a few dozen micrometers, that is partly treated on its two sides, is mounted on a conductive support via bonding which permits good electric continuity between the contacted elements.

After this conductive bonding, the structure obtained is subjected to the last technological fabrication steps (for example metallisation) of the device.

Therefore metal bonding by molecular adhesion is chosen which is compatible with the technological fabrication steps of the device under consideration, these steps being conducted before and after metallic bonding.

Particular care must be taken that the heat treatments used during the metal bonding process are compatible with the technology of the device under consideration.

In the example of embodiment of a structure such as a thin film or wafer in silicon which is made integral with a silicon support via conductive bonding, preferably metals or metal compounds are chosen that are able to form stable alloys with silicon during formation of the metal bonding.

Table I at the end of this description is taken from the following document: M. A. Nicolet & S. S. Lau, “Silicides”, VLSI Handbook, Academic Press, Chapter 24, pages 415 to 433, 1985.

It gives a few examples of metals which may be used for conductive bonding together of silicon wafers by molecular adhesion, and of alloys (silicides) formed between these metals and the silicon and, for each silicide, the temperature at which this silicide is formed and its resistivity value.

Various variants for conductive bonding, by molecular adhesion, of a thin silicon wafer may be used:

Element A (see table I) may be deposited on the rear side of the thin wafer and/or on the front side of the conductive support.

Or instead, the A-Si silicide may be deposited on the rear side of the thin wafer and/or on the front side of the conductive support.

TABLE I

| | | Formation | |
|---|---|---|---|
| Element | Silicide | temperature | Resistivity |
| (A) | (A-Si) | (° C.) | (10⁻⁶ ohm · com) |
| Ti | TiSi | 500 | 63 ± 6 |
| | TiSi₂ | 600 | 10-25 |
| V | VSi₂ | 600 | 50-55 |
| Cr | CrSi₂ | 450 | >250-1420 |
| Mn | MnSi | 400-500 | 200-260 |
| | MnSi₂ | 800 | 6500-13000 |
| Fe | FeSi | 450-550 | 260-290 |
| | FeSi₂ | 550 | — |
| Co | CO₂Si | 350-500 | 60-130 |
| | CoSi | 375-500 | 90-170 |
| | CoSi₂ | 550 | 18-65 |
| Ni | Ni₂Si | 200-350 | 20-25 |
| | NiSi | 350-750 | 14-50 |
| | NiSi₂ | 750 | 34-60 |
| Mo | MoSi | 525 | 21-200 |
| Pd | Pd₂Si | 100-300 | 25-35 |
| | PdSi | 850 | — |
| Ta | TaSi₂ | 650 | 8.5-55 |
| W | WSi₂ | 650 | 50-200 |
| Pt | Pt₂Si | 200-500 | — |
| | PtSi | 300 | 28-40 |

1. Electronic device comprising an active part (38, 40,42), a first thin layer (36) which is made of a semiconductor material and in which this active part is formed, and a substrate (44) made of an electrically conductive material, this device being characterized in that it also comprises a carrier recombination zone (46) which is located between the substrate and the first thin layer and which also ensures a resistive electric contact between this substrate and this first thin layer.

2. Device as in claim 1, wherein the carrier recombination zone is a second thin layer (46) which is made of an electrically conductive material and which ensures electrically conductive bonding between the substrate and the first thin layer.

3. Device as in either of claims 1 and 2, wherein the two sides of the first thin layer (36) are treated to form active zones (38,40) of the device.

4. Device as in any of claims 1 to 3, wherein the material in which the carrier recombination zone (46) is made is a metal.

5. Device as in any of claims 1 to 3, wherein the material in which the carrier recombination zone (46) is made is a semiconductor/metal alloy.

6. Device as in claim 5, wherein the alloy in which the carrier recombination zone (46) is made is chosen so that it is stable with respect to the materials in which the substrate and the first thin layer are respectively made.

7. Device as in any of claims 1 to 6, wherein the material in which the substrate (44) is made is a highly doped semiconductor, in particular highly doped silicon.

8. Device as in claim 7, wherein the material in which the carrier recombination zone (46) is made is a metal and this metal is chosen so that, when fabricating the resistive electric contact, it forms a stable alloy with the highly doped semiconductor in which the substrate is made and with the semiconductor material in which the first thin layer is made.

9. Device as in any of claims 1 to 6, wherein the material in which the substrate (44) is made is a metal.

10. Device as in claim 9, wherein the carrier recombination zone (46) is made in the metal in which the substrate is made and is formed by part of this substrate.

11. Process for fabricating an electronic device, this process being characterized in that it comprises the following steps:
part (38, 42) of the device is formed in a standard semiconductor substrate (52), on the front side of this standard semiconductor substrate,
a treatment support (54) is fixed to the front side of the substrate,
the standard semiconductor substrate is thinned via its rear side, so as to transform it into a thin layer (36),
another part (40) of the device is formed in the standard semiconductor substrate so transformed, on the rear side of this standard semiconductor substrate,
on the rear side of this standard semiconductor substrate and/or on a side of an electrically conductive substrate, a thin layer is deposited formed of a metal or of a metal/semiconductor alloy,
via the thin layer formed of the metal or metal/semiconductor alloy, electrically conductive bonding is carried out between the electrically conductive substrate and the thin layer into which the standard semiconductor substrate was transformed, and
the treatment support (54) is removed.

12. Process for fabricating an electronic device, this process being characterized in that it comprises the following steps:
part (38,42) of the device is formed in a standard semiconductor substrate (52), on the rear side of this standard semiconductor substrate,
on the rear side of this standard semiconductor substrate and/or on a side of an electrically conductive substrate, a thin layer is deposited formed of a metal or a metal/semiconductor alloy,
electrically conductive bonding is carried out between the electrically conductive substrate and the standard semiconductor substrate, via the thin layer,
the standard semiconductor substrate is thinned via its front side so as to transform it into a thin layer (36), and
another part (40) of the device is formed in the standard semiconductor substrate so transformed, on the front side of this standard semiconductor substrate.

13. Process as in either of claims 11 and 12, wherein electric contacts (48,50) of the device are also formed on the thin layer in which the standard semiconductor substrate was transformed, and on the electrically conductive substrate.

14. Process as in any of claims 11 to 13, wherein the electrically conductive substrate (44) is made of a material chosen from among highly doped semiconductors in particular highly doped silicon, and conductors in particular metals.

15. Process as in claim 14, wherein the electrically conductive substrate is made of a material chosen from among highly doped semiconductors, in particular highly doped silicon, the metal or the metal/semiconductor alloy being chosen so that, after annealing subsequent to electrically conductive bonding, it forms a stable alloy with the material in which the electrically conductive substrate is made and with the material in which the standard semiconductor substrate is made.

16. Process as in claim 14, wherein the electrically conductive bonding step is preceded by a preparative step to prepare at least one of the two sides to be assembled by electrically conductive bonding, so as to promote this bonding.

17. Process as in any of claims 11 to 16, wherein electrically conductive bonding (46) is chosen from among bonding by soldering, bonding by thermal compression and bonding by molecular adhesion.
